(19) United States
(12) Patent Application Publication
(10) Pub. No.: US 2026/0061800 A1
(43) Pub. Date: Mar. 5, 2026

(54) Electrical Flow Heater for a Vehicle, in Particular an Electric Vehicle, Operating Method for the Flow Heater and Vehicle

(71) Applicant: Bayerische Motoren Werke Aktiengesellschaft, Muenchen (DE)

(72) Inventor: Johannes HOEDL, Muenchen (DE)

(21) Appl. No.: 19/103,411

(22) PCT Filed: Oct. 10, 2023
(86) PCT No.: PCT/EP2023/078050

§ 371 Date: Feb. 12, 2025

(30) Foreign Application Priority Data
Nov. 9, 2022 (DE) 10 2022 129 536.2

(51) Int. Cl. B60H 1/00; B60H 1/22; F24H 15/128; F24H 15/407; H03K 3/017; H05B 1/02

(52) U.S. Cl. CPC B60H 1/0073; B60H 1/00278; B60H 1/00392; B60H 1/2221; F24H 15/128; F24H 15/407; H03K 3/017; H05B 1/0236; H05B 2203/005

(57) ABSTRACT

A method is provided for operating an electrical flow heater in a vehicle, in particular an electric vehicle, wherein the flow heater has multiple electrical heating circuits for electrically generating a respective heating power in a heating section through which a medium to be heated flows, and a power control of the respective heating power of the respective heating circuit is carried out by a control circuit by controlling a respective controllable electrical switch element of the respective heating circuit. A sum of the heating powers is adjusted to a total heating power. With the control circuit, a distribution of the total heating power into the heating powers of the heating circuits is carried out according to configuration data, wherein the configuration data is independent of a current temperature of the medium to be heated.

### BACKGROUND AND SUMMARY

The invention relates to a method for operating an electrical flow heater in a vehicle, in particular an electric vehicle. The method proceeds from the assumption that the flow heater comprises multiple electrical heating circuits. A heating circuit can be provided in the form of an electric circuit which comprises at least one heating wire and/or at least one heater coil. During the operation of a heating circuit, temperature gradients and/or temperature changes are generated on the respective heating wire or on the respective heating coil which are associated with material loads which can potentially result in unwanted and premature material fatigue, the prevention of which is intended. The invention also comprises a flow heater, which can be operated according to the method, and a vehicle having such a flow heater. In particular, the vehicle is provided in the form of an electric vehicle.

In electric vehicles, e.g. battery electric vehicles (BEVs) and plug-in hybrid electric vehicles (PHEVs), the heating/heat-up function of the interior is not executed by means of waste heat from the combustion engine, as in the case of a combustion engine vehicle, but additionally, or exclusively, by means of an electrically powered flow heater. Alternatively or additionally, heat-up to the requisite temperature can be executed by means of a heat pump, which captures heat from the high-voltage battery or the electric motor. If this is not sufficient (e.g. on cold days or at the start of travel), the coolant also undergoes heat-up by means of an electrical heater, namely, an electrical flow heater (EFH). The EFH is further employed for conditioning the high-voltage system (HVS) of the electric vehicle such that, in many operating situations, the charging time is shortened.

The electric heating function in the electrical flow heater (EFH) has a very high power (e.g. up to 9 kW). The operating mode of the model of flow heater which is fundamentally considered herein is as follows: the coolant (the medium which is to be heated) flows through the electrical heater or heating section and thus undergoes heat-up on one or more heating plates by means of a plurality of electrical heating circuits. Each heating circuit is connected to the high-voltage supply (HVS) via at least one dedicated power driver (e.g. special transistors). Actuation of the power drivers is executed e.g. by pulse-width modulation (PWM), by means of control electronics (control circuit), whereby the heating power of the heating circuits can be controlled separately or individually. In general, all the heating circuits are supplied with an equal level of power.

An electrical flow heater is known from DE 4 211 590 C1, having a cold water inlet, a control device, a heating section and a warm water outlet, the heating section of which comprises at least two individually controllable and/or switchable heating elements, at least one of which is controllable in a heat demand-dependent manner.

The object of the present invention is the operation of an electrical flow meter for a vehicle in a material-conserving manner.

According to the invention, this object is fulfilled by the subject matter of the independent patent claims. Advantageous embodiments of the invention are the subject matter of the dependent patent claims, the description and the figures.

By way of a solution, the invention comprises a method for operating an electrical flow heater in a vehicle. The method proceeds from the assumption that the flow heater comprises multiple electrical heating circuits for the electrical generation of a respective heating power in a heating section through which a medium which is to be heated flows. The heating section can be formed, for example, by a pipe or a duct, through which a throughflow or flux of the medium can be directed. The medium can be provided, in a known manner, in the form of a fluid, in particular in the form of a liquid such as, for example, water or oil. The heating circuits can execute the heat-up of the same heating section, in combination, or of different branches or segments of the heating section. In order to execute the heating thereof, the heating circuits are supplied with electric power.

To this end, a control circuit actuates a respective controllable electrical switching element (one or more semiconductor switches, MOSFETs or power drivers) of the respective heating circuit, in order to execute a power control of the respective heating power of the respective heating circuit, wherein the sum of the heating powers of the heating circuits is adjusted to a total heating power, which can be stipulated for the flow heater. For example, the total heating power can be dictated by a temperature control circuit, wherein the distribution thereof can be controlled according to configuration data.

Power control in the individual heating circuits can be executed, for example, on the basis of pulse-width modulation (PWM), by means of which the respective switching element can be switched between different electrical circuit states (for example, electrically conducting and electrically non-conducting). In the respective switching element, in each case, one or more semiconductor switches, for example at least one transistor, such as a MOSFET (metal oxide semiconductor field effect transistor) and/or a respective bipolar transistor, can be provided. In general, electrical switching elements of this type are described as power drivers. As each heating circuit comprises a dedicated switching element, the control circuit can execute an individual control or adjustment of each heating circuit, with respect to the heating power which is converted therein or which is delivered therein. Overall, a total heating power is generated which, for example, in the case of an air-conditioning system, can be predetermined by a user who has dictated or preset a heating level for the heat-up of an interior space. In a manner which is known per se, a heating plate or multiple heating plates can also be arranged in the heating circuits, at least in places, each of which can be formed, for example, of a ceramic material. Electrically conductive lines of the respective heating circuit can be bonded, for example, to the respective heating plate, or embedded therein.

In order to reduce material fatigue which, during the operation of heating circuits, can be associated with temperature fluctuations and/or temperature concentrations (hotspots) which are generated in the heating plates and/or in the heating section, according to the invention, it is provided that the control circuit executes a division or distribution of the total heating power into the heating powers of the heating circuits, in accordance with configuration data (which are saved in a data memory of the control circuit), wherein the configuration data, or the division which is dictated by the configuration data, are independent of the current temperature of the medium which is to be heated. By means of the configuration data, a power profile or power distribution is thus further imposed upon the actual temperature control.

The term “configuration data” is thus to be understood in a comprehensive manner, by way of a data-based control of the control circuit which can be implemented in a variety of ways. Potential examples can be provided as follows: configuration data can be embodied as a program-based control function of the control circuit. Additionally or alternatively, configuration data can comprise at least one characteristic map which, for different operating values and/or different operating situations, can respectively provide another distribution of the total heating power between the individual heating circuits. Additionally or alternatively, configuration data can dictate parameter values in a control software, for example at least a threshold value and/or a limiting value and/or an upper limit. To this end, additionally or alternatively, configuration data can be implemented by means of a parametric function, which defines a functional dependence between at least one operating variable and the heating power which is to be set for at least one heating circuit. The total heating power can lie, for example, within a range of 1 kW to 15 kW. For flow heaters of this order of magnitude, material fatigue has proved to be a specific technical issue. As the total heating power to be delivered or generated, in accordance with the dictates of configuration data, can now be distributed or divided between the different heating circuits, each heating circuit can thus be operated with a different heating power. The necessity can thus be taken into consideration for one or more of the heating circuits to be operated in a more protective manner, in comparison with at least one other heating circuit, for example on the grounds of the location thereof in a hotspot in which, as a result of a build-up of heat or warmth, a disproportionately high localized heat-up can occur (in comparison with the remaining heating circuits). By the associated configuration of the control circuit such that the latter executes the distribution of the total heating power between the individual heating circuits in accordance with configuration data which are not dependent upon the actual temperature control function, but which dictate the ratio of distribution in general, namely, for different setpoints of the total heating power, actual temperature control or temperature regulation, by means of characteristic data, can thus be superimposed or expanded by the operating strategy for the protective operation of the flow heater. Power control by the actuation of switching elements can be implemented by means of a method from the prior art, for example a regulation of current intensity and/or a switch-on time.

By way of derivation from simulation data of a digital simulation, an anticipated restriction of the potential service life/operating cycles of a given electrical flow heater (EFH) can be ascertained. It can thus be ascertained whether and/or where it is to be anticipated that the flow heater might sustain a defect in advance of its anticipated or stipulated service life, in end-user operation. Any replacement would be complex, over and above the price of parts alone, in consideration of the necessity for the vehicle to be shutdown/secured vis-à-vis the high-voltage supply, any intervening parts to be removed, fluid lines to be drained and dismantled and, not least, in consideration of the associated generation of major dissatisfaction for the end-user. By the reduction of temperatures in hotspots and/or temperature gradients in excess of a maximum value, any failure or outage of a heating system which is situated therein can be prevented.

The invention also comprises further developments, which permit the achievement of additional advantages.

According to one further development, configuration data are permanently stipulated or saved in the control circuit. For example, configuration data can be saved in, or imposed upon the control device at the time of manufacture of the vehicle. If the vehicle in which a flow heater is to be employed is known, by the imposition or saving of configuration data in the control circuit, the latter can thus be configured for the vehicle, for example in the interests of considering which of the heating circuits of the flow heater it is necessary to operate with a reduced or lowest electric power, in relation to the remaining heating circuits, on the grounds that, for example, by reference to the above-mentioned simulation data of a simulation, a hotspot or heat build-up has been identified for this heating circuit, when the latter is located in its installation position in the vehicle. Thus, by means of one and the same model of a flow heater, a protective operation can be implemented for different vehicle models, with no structural adaptation of the flow heater to the respective vehicle model.

Alternatively, configuration data can be modified (updated) during the operation of the control circuit. By a subsequent modification of configuration of this type, for example by means of an update of configuration data in the control circuit, a response to new findings and/or long-term prototype trials can thus be delivered and, additionally, an adjustment of the operating mode, i.e. of the distribution of heating power between the heating circuits, can be executed in vehicles which are already in use by customers.

An in-service switchover between, or selection of different configuration data can be executed by the control circuit, i.e. depending upon a current operating situation detected, the actuation of heating circuits can be executed in accordance with the configuration data selected. In this variant, a number of different operating situations can be taken into consideration in the configuration data. For example, a number of different vehicle models can be considered in the configuration data, and the flow heater, by the selection or switchover of configuration data, can be upgraded for the respective vehicle model, wherein the control circuit, by the selection of elements of the configuration data which are appropriate to the vehicle or to the vehicle model thereof, can then adapt its operation to the vehicle model of the vehicle. For example, the control circuit, by means of a signal from an on-board communication network, for example a communication bus, can indicate the vehicle model of the vehicle in which the flow heater is installed. The control circuit can then adapt automatically to the vehicle model, with respect to the operating mode of heating circuits and, in particular, with respect to the distribution of heating power.

By reference to exemplary potential configurations, it is described hereinafter what elements can be controlled or stipulated by configuration data in the control circuit, in order to achieve a protective operation of the flow heater.

According to a further development, by means of the configuration data, a condition for actuating the switching elements is stipulated, which dictates a respective upper limit for the heating power of one, a number, or each of the heating circuits. In other words, it is prevented that a heating power in excess of the upper limit is accepted by, set on, or delivered to a respective heating circuit. As a result, any hotspot or overheating in the respective heating circuit can be prevented. By means of the distribution associated with the stipulation of upper limits, any inconsistent wear of heating circuits can be prevented. By the variation of the upper limit over time, moreover, a targeted matching of the wear of individual heating circuits to the respective state of wear of another heating circuit can be achieved or coordinated.

According to a further development, by means of the configuration data, a condition is stipulated which provides for a (power-rated) coordinated switching of the switching elements of at least two of the heating circuits, the heating lines of which are arranged in direct mutual proximity in the flow heater, wherein coordinated switching provides for a dependence of the heating power and/or a circuit state of one of the heating circuits which is switched in a coordinated manner upon the heating power or circuit state of another of the heating circuits which is switched in a coordinated manner. The heating lines thus described can be the above-mentioned heating wires and/or heater coils, of which each heating circuit can respectively comprise one or more. By the consideration of adjacently arranged heating lines, i.e. such heating lines between which no further heating line of another heating circuit is routed or arranged, thermal hotspots can be prevented. For example, by the coordinated switching of such heating circuits, it can be provided that, by way of a condition, a sum of the heating powers which is simultaneously delivered by these heating circuits is smaller than a stipulated maximum value. A maximum value of this type can be ascertained, for example, by means of a simulation. Such a maximum value can also be set in accordance with a flow speed or throughflow rate (in liters per minute) of the medium. Thus, for example, in a region in which the heating lines assume the smallest mutual clearance, a potential hotspot at this location can be prevented, or the temperature thereof can be maintained below a maximum value, if the evacuation of thermal energy by the medium would otherwise be too slow.

According to a further development, by means of the configuration data, a condition is stipulated which dictates a synchronized switching, in particular a staggered and/or phase-displaced switching of at least two of the switching elements. A synchronized switching signifies that switching is executed in a temporally tuned manner, for example with a temporal offset. As a result, for example, in the event of the presence of inductive electrical components in heating circuits, any cumulative action or superimposition of simultaneously generated switching spikes caused by induction associated with the interruption of a current flux can be prevented. Instead, such switching spikes are generated in a staggered manner. In the event of periodic or cyclical switching, e.g. in the case of PWM, by means of the staggering of switching processes in multiple heating circuits, for example, a destructional neutrality or eradication in the event of an emission of electromagnetic radiation and/or in the event of a ripple voltage in the electric power supply grid can be achieved such that, for example, other vehicle components such as, for example, electronic control devices remain undisturbed.

According to a further development with respect hereto, a phase-displaced switching is dictated for such heating circuits, the electrical heating lines of which and/or the electric power supply lines of which are arranged in immediate mutual proximity (with no other intervening line). Such an adjoining arrangement of heating lines and/or of power supply lines is associated, for example, with a twisted-pair arrangement of power supply lines and/or with an electrical or electromagnetic shielding of a power supply line. In order to promote an eradicative effect, it is even possible for heating lines to be deliberately laid in a mutually parallel arrangement at the time of production of heating plates, particularly in the form of heater coils, in order to enable the improved or advantageous operation thereof with respect to electromagnetic compatibility (EMC) by means of phase-displaced switching, in particular with a phase displacement of 180°. The antenna effect, by means of the destructional neutrality associated with phase displacement, can then be offset by the antenna effect of other coils. Accordingly, a phase-displaced pulsed-mode operation of at least two of the heating circuits can thus be provided, e.g. with a pulse rate in the range of 5 Hz to 50 kHz which, in particular, can be associated with or employed in pulse-width modulation, which operation is thus executed with a phase displacement, in particular of 180 degrees.

With respect to pulse-width modulation, according to a further advantageous configuration, by means of the configuration data, synchronized switching is dictated either for all, or only for a number of switching frequencies which are provided for, or potentially employed in PWM. Given that, in pulse-width modulated operation, pulse frequencies vary within a stipulated frequency range, or variable pulse switching frequencies are provided, it can occur that only occasional and specific harmful switching frequencies will then result in electromagnetic interference which is generated in the vehicle by the heating circuits and interferes, for example, with a radio transmitter. If such switching frequencies are known, by the dictation of corresponding configuration data for the latter, an eradication or damping of electromagnetic interference radiation can be provided by means of the above-mentioned synchronized switching.

According to a further development, configuration data provide for different installation positions and/or spatial installation locations of the flow heater in the vehicle and/or for different distributions of the total heating power for different vehicle models and, by means of the control circuit, such configuration data are selected as are provided for the actual installation position and/or installation location of the flow heater. The installation position and/or installation location can be signaled by stipulated positional data. Actuation of switching elements, and thus the adjustment of heating power values in the switching elements, is thus executed in accordance with the selected configuration data.

According to a key finding, the installation position, i.e. the spatial proximity to other vehicle components of the vehicle, and/or the installation location, for example in an upside-down or horizontal arrangement, can influence temperature distribution and/or thermal dissipation in the flow heater. Moreover, proximity to other vehicle components can also generate an overheating or material fatigue at that location, associated with thermal radiation. By the dictation of corresponding configuration data, the installation position and/or installation location can then be considered in the distribution of the total heating power between the heating circuits. If the installation position and/or installation location in the vehicle at which the flow heater is installed is known, for example by means of a signaling of the vehicle model which is executed via the above-mentioned on-board communication network, the operation of the flow heater can then be correspondingly adapted or configured. For example, a control device of the vehicle can indicate which vehicle model is involved. Identification of the potential location of manifestations of fatigue associated with installation positions and/or spatial installation locations can be enabled or executed, in the manner described, by simulation and/or by means of damage report statistics.

During the operation of the flow heater, variably favorable or variably wear-inducing operating states can occur. A response thereto can be enabled by the corresponding stipulation of state-specific configuration data, wherein the distribution of heating powers of the heating circuits is adapted to the operating state.

According to a further development, the control circuit executes a different setting of distribution and/or a different actuation of switching elements, according to configuration data for different operating states of the flow heater, which are distinguished with respect to flow conditions of the medium (flow speed, throughflow rate), and/or for different operating modes, which are distinguished with respect to a fluidic coupling of the heating section with different vehicle components of the vehicle. It can thus be taken into consideration, for example, that the cooling action executed by the medium on the flow heater diminishes as the flow speed and/or throughflow rate decreases. Additionally and alternatively, hydraulic conditions which are potentially associated with the coupling of different vehicle components, for example of an air-conditioning compressor on the one hand, and of a temperature-control system of a vehicle traction battery on the other, can be considered as different operating modes, and corresponding configuration data delivered accordingly. By means of these data, the actuation of switching elements (for example, the coordinated operation thereof) or the distribution of heating power (for example by the dictation of an upper limit in accordance with the operating mode) can be varied or adapted to the operating mode. The operating state or operating mode can be gauged by reference to a sensor circuit of the flow heater itself (e.g. with respect to the flow speed and/or pressure of the medium) and/or can be indicated by another control device of the vehicle, which controls e.g. valve for hydraulic coupling.

According to a further development, by means of the control circuit, in accordance with the configuration data, the distribution of the total heating power and/or the actuation of switching elements is executed on the basis of a respective operating history. In particular, the operating history indicates an age and/or hours of service and/or a total quantity of energy converted by the respective heating circuit. If it is known from the operating history, for example, that the flow heater has executed a number of cold starts which exceeds a predetermined threshold value, a heating circuit which is particularly susceptible to wear or fatigue by such a cold start can be restricted or adapted, by means of the configuration data, with respect to the heating power which is converted thereby. Additionally or alternatively, an absolute age and/or a number of hours of service and/or a total quantity of energy converted in a heating circuit can be ascertained or logged. A redistribution or displacement of power can then be triggered, in the event that the operating history indicates that, for at least one of the heating circuits, a wear limit has been achieved or a state of wear has achieved a predetermined limiting value. A consistent material fatigue and/or a consistent wear of heating circuits can be enabled accordingly.

The control principle of the flow heater is described hereinafter, again in general terms.

By means of configuration data, for different potential operating situations in which the flow heater can be continuously and/or intermittently operated in the vehicle, differing e.g. proportional components of the respective heating power in the total heating power and/or upper power limits for two or more, or for all the heating circuits can be dictated. By the control circuit, correspondingly, by means of a dedicated sensor circuit and/or by reception from another control device, situation data can be ascertained which indicate the actual operating situation. Actuation of switching elements of the heating circuit can be executed in accordance with those configuration data which are dictated for the operating situation which is indicated by the situation data. An operating situation is already defined, for example, by the circumstance whereby the flow meter is permanently installed and/or remains in a specific vehicle model of a vehicle. In this case, the above-mentioned adaptation to the vehicle model and/or to the installation position and/or installation location can be executed. A change of actuation of the switching elements and/or of the distribution of heating powers can be executed in response to the ascertainment of a change in the current operating situation, which can also vary during the operation of the vehicle, on the grounds that, for example, different vehicle components can be fluidically connected to the flow heater at different times and/or throughflow rate of the medium is varied. By the indication of the current operating situation by the control circuit, and/or by the ascertainment of the current operating situation by the control circuit itself, situation data are generated, by reference to which configuration data are then selected or, by reference to configuration data, the distribution of heating power and/or the actuation of switching elements can be executed differently for different operating situations.

According to a further development, configuration data incorporate a code flag, according to the state of which a control is executed, either to the effect that distribution is activated at all times, or is only activated in accordance with a vehicle parameter logic, in particular with respect to a national version, a target market, material variants of the heating plates and/or in consideration of a dedicated cold climate vehicle. This means that the method, in addition to continuous activation in a vehicle, can also be encoded in accordance with a vehicle parameter logic, including a national version, target market, material variants of the heating plates (e.g. if these originate from multiple supplies, or are (or must be) sourced from a specific market), or a distinction as to whether a dedicated cold climate vehicle is involved. This information is present in the vehicle order, and can be employed for encoding.

According to a further development, situation data are ascertained from an on-board network to which the flow heater is coupled, and/or by means of a sensor circuit of the flow heater. By means of an on-board communication network, for example a CAN bus (CAN=controller area network), a signal can be delivered to the control circuit by at least one other vehicle component, as to which operating condition is currently in force and/or which operating mode is to be set in the flow heater and/or which configuration data are valid. By means of a sensor circuit, the control circuit can independently ascertain, within the vehicle, which configuration data are to be employed. For example, the transmitter circuit can comprise a gyro sensor, by means of which an installation location of the flow heater can be independently ascertained by the gyro sensor and by the control circuit thereof.

According to a further development, the control circuit, further to the employment of configuration data and in a servicing mode, receives new configuration data, and configuration data are entirely or partially replaced and/or expanded by the new configuration data thus received. In the servicing mode which, for example, can be set in the flow heater during an over-the-air update and/or in a workshop, configuration data can be refreshed or expanded. Even in service, or in the course of its service life in the vehicle, the flow heater can thus be supplied with further information on the susceptibility of heating circuits to wear, and corresponding countermeasures can be implemented.

By way of a further fulfilment of the object, the invention comprises an electrical flow heater, comprising multiple electrical heating circuits, each of which is connected via a respective and controllable electric switching element to a terminal apparatus for supplying electrical energy to the respective heating circuit. The control circuit of the flow heater can be based, for example, upon at least one microcontroller and/or at least one microprocessor and/or an ASIC (application-specific integrated circuit). The process steps described herein can be implemented in the form of a software or program code in the control circuit, and saved in a data memory of the control circuit. The terminal apparatus can comprise, for example, a plug connector or a socket having electrical contact elements such that, by means of the terminal apparatus, the flow heater can be electrically connected to an on-board electrical network of the vehicle, for example a high-voltage on-board network (the term “high voltage” describes electric voltages greater than 60 V, in particular greater than 100 V).

The flow heater comprises a control circuit, which is provided for the power control of electric power which is converted by means of the switching elements in the respective heating circuit (heating power), wherein the control circuit is designed for executing an embodiment of the method described herein.

By way of a further fulfilment of the object, the invention comprises a vehicle having an embodiment of the electrical flow heater described herein. As described above, in particular, the vehicle is an electric vehicle and thus, for example, the above-mentioned BEV or PHEV. In the vehicle, it is thus possible for an operating state and/or an operating history to be taken into consideration and, by means of configuration data, to control the extent to which or how the distribution of heating powers is to be executed in order to achieve the total heating power in the heating circuits. A local or internal temperature distribution in the flow heater is thus enabled by means of configuration data, in accordance with stipulations pertaining to material fatigue or wear, or electromagnetic compatibility.

Further features of the invention proceed from the claims, the figures and the description of the figures. Features and combinations of features specified in the preceding description, together with features and combinations of features specified hereinafter in the description of the figures and/or represented in the figures alone, are not only applicable in the respectively indicated combination, but also in other combinations, or in isolation.

The invention is described in greater detail hereinafter with reference to a preferred exemplary embodiment, and in consideration of the drawings.

### BRIEF DESCRIPTION OF THE DRAWINGS

FIG. 1 is a schematic representation of one embodiment of the vehicle according to the invention, having an electrical flow heater; and

FIG. 2 is a schematic representation of the flow heater, having different embodiments of heating circuits.

### DETAILED DESCRIPTION OF THE DRAWINGS

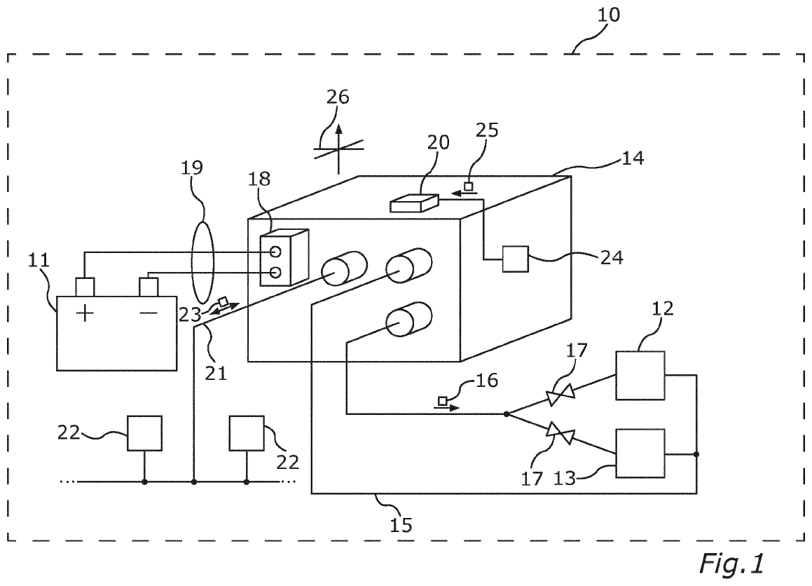

FIG. 1 shows a vehicle 10, which can be a motor car, in particular a passenger car. The vehicle 10 can be configured in the form of an electric vehicle. In the vehicle 10, an electrical energy source 11 can be provided which, for example, can be a vehicle battery (a traction battery or high-voltage battery). For the heat-up or heating of at least one vehicle component 12, 13, a flow heater 14 can be provided in the vehicle 10, which can be fluidically coupled by means of a heating circuit 15 to the vehicle components 12, 13, in order to execute a heat-up of a medium 16, for example a water-based or oil-based fluid. A state of the fluidic coupling can be varied, for example by means of valves 17. By way of exemplary vehicle components 12, 13, an air-conditioning system for a passenger compartment of the vehicle 10 and/or a temperature control system for the vehicle battery can be provided.

For a supply of energy or a supply of electric power to the flow heater 14, the latter can be connected by means of a terminal apparatus 18, for example an electric socket or an electric plug connector, to an on-board electrical network 19, which can be supplied with electric power by the energy source 11.

The flow heater 14 can comprise a control circuit 20, which can be coupled via an on-board communication network 21 to at least one further electronic component 22, for example to a respective electronic control unit (ECU) for an exchange of situation data 23. The on-board communication network 21 can be based, for example, upon the above-mentioned CAN bus and/or an Ethernet network and/or a LIN bus. Situation data 23 can indicate e.g. a circuit state of the valves 17. Additionally and alternatively, a sensor circuit 24 can be provided in the flow heater 14 itself, by means of which the control circuit 20 can capture sensor data 25 in the form of situation data, for example a spatial installation location 26, which is symbolically represented in FIG. 1 by a coordinate system.

In the vehicle 10, the flow heater 14 can be operated in a protective manner, with respect to material wear and/or material fatigue.

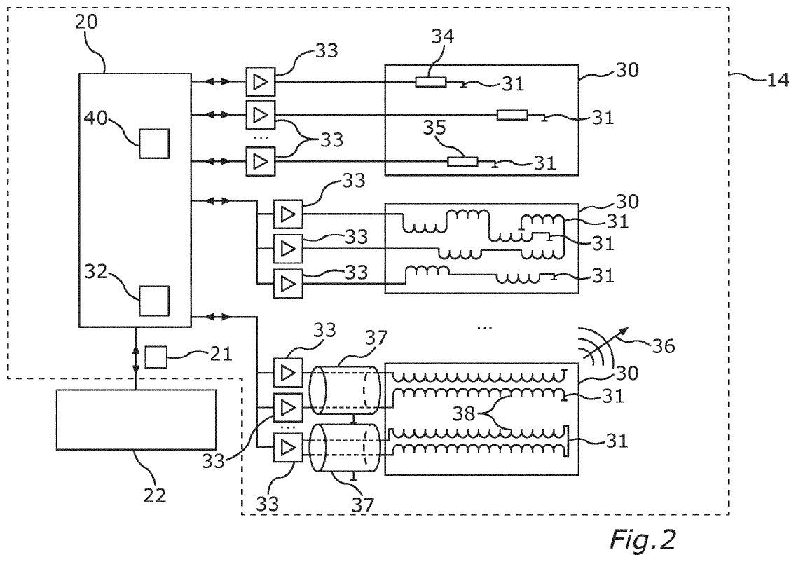

To this end, FIG. 2 illustrates heating plates 30 which, for example, can be formed of a ceramic material, and over which a passing stream or passing flow of the medium 16 can be directed, thus forming a heating section for the medium. For the heating of the heating plates 30, electrical heating circuits 31 can be provided, i.e. electrical circuits which can be supplied with electric power from the on-board electrical network 19. A requisite or requested total heating power demand 32 can be received via the on-board communication network 21, for example from one of the electronic components 22, for example an air-conditioning device, or from on-board electronics in general. The respective heating power of the heating circuits 31 can be adjusted individually by the control circuit 20, in consideration of the current in the heating circuit or the electric power, by means of a respective switching element 33, which can be respectively based, for example, upon at least one semiconductor power breaker, for example at least one transistor and/or thyristor. This individual actuation of switching elements for the adjustment of heating power by the control circuit 20 can be implemented, for example, on the basis of pulse-width modulation. In the respective heating circuit, for example by means of heating wires 34 and/or heater coils (heating coils), electric power can be converted into heat, and released into the heating plates 30 or onto the heating plates 30.

As a result, on the heating plates 30 and/or in the heating circuits 31, different temperature distributions and/or temperature gradients can be generated in the heating plates 30 or on the heating circuits 31. Accordingly, the generation or formation of hotspots or heat concentrations can occur, at which a material fatigue can be greater than in other regions of the flow heater 14. Additionally or alternatively, in particular, electromagnetic radiation 36 can be generated.

This radiation can be structurally counteracted, for example by a shielding 37 of feeder lines or power supply lines of the heating circuits and/or by means of a geometrical arrangement 38 of heating circuits, or the impact of electromagnetic radiation 36, or the strength thereof, can be attenuated. Additionally, by means of a corresponding actuation of switching elements 33, a reduction of electromagnetic radiation 36 can be achieved. The switching behavior or actuation of switching elements 33, or the distribution of the total heating power demand 32 with respect to the individual heating power of the respective heating circuits 31, can be executed in accordance with configuration data 40, which can be saved in the control circuit 20 or which can be implemented, and which are based upon findings or information with respect to the formation of hotspots associated with different operating modes and/or different installation locations of the flow heater 14. Such information can be based, for example, upon simulations and/or upon fault reports for vehicles which are already in service.

In different vehicle models, the same heater is installed in different positions and with different orientations. There is a resulting variation, inter alia, in the temperature distribution in the EFH on the heating plates thereof, in the entire component, and in the flow behavior of the coolant. This can even result in functional differentiations. However, the heating function is not adapted thereto, as a result of which it does not operate in an optimum manner, and the effective efficiency thereof (how much energy, in the form of heat, is released to the coolant) is restricted. As a result of the high heating power demand and the requisite structural space, and in order to fulfil requirements, it is necessary for the heating plate materials to be of an exceptionally high quality. High proportional costs are generated as a result. Moreover, as a consequence of this high power, an increased risk is generated of the occurrence of heating power breakdowns or other defects. As a result, the EFH has a limited service life, and there is even a risk of the immobilization of the vehicle, thereby resulting in end-user dissatisfaction and high warranty costs. Depending upon the operating mode, the charging time of the vehicle can also be significantly extended.

According to the disclosure, the individual heating plates or heating circuits can be individually actuated, such that it is no longer necessary for all the latter to be operated at the same power, which power can be distinguished according to the circumstance.

Various options are available for communicating the operating state, operating history, installation location and orientation assumed by the heating plates. According to a first option, for example, a signal containing this information is transmitted via the on-board network. To this end, it is necessary for this information to be established beforehand for each vehicle model, and for the requisite software to be adapted accordingly. According to a second option, this process is automated, wherein further sensors (e.g. a simple gyroscope) are fitted to the plates, as a result of which the latter can independently detect their own position. Further to the establishment thereof, it is then intended that all the plates should no longer be supplied with an equal power, but that power control should be optimized according to the circumstances. One example would be an increased switch-in of heating plates which are installed lower down, on the grounds that heat rises (according to efficiency), and a corresponding inverse arrangement. Alternatively, heating plates which are installed lower down are switched-in to a reduced extent, in comparison with those arranged above, in order to permit a more effective evacuation of a temperature loading in the component, of the other heating plates and/or of the electronics. According to a further approach, heating plates or elements thereof which, with respect to flow properties, assume a higher risk, are operated with a situationally reduced power. In the event of a corresponding synchronization and design layout, this approach also results in an improved outcome with respect to the radiation of electromagnetic interference from components. Particularly in the event of the employment of very rapid, and thus more energy efficient power drivers, radiated electromagnetic power represents an impediment, the improvement of which thus serves the interests of the energy efficiency of the EFH. According to a further variant, actuation is synchronized in a paired arrangement, in order to execute control with a 180° phase displacement. In the event of a spatially confined geometrical arrangement of feeder lines to the heating plates (e.g. by means of coaxially routed and/or shielded conductors) and a spatially confined geometrical arrangement of heating wires on the heating plates, this would enable a further suppression of any inevitable sources of EMC interference. In consideration of the ongoing and anticipated development of even more rapid power drivers, this factor will assume even greater significance in future.

According to potential implementations, it is provided that an additional on-board network signal is required, in order to control power switches for the purposes of an operating mode and, potentially, to enable the communication of information via the on-board communication network (e.g. the CAN bus). However, the resulting one-off cost is extremely limited and, primarily, is not reflected in proportional component costs of the vehicle. Moreover, rather than a single power output for the control of all switches, a dedicated terminal for each switch will now be required. However, this is a conventional technical arrangement in any event, on the grounds that small or low-capacity power driver modules for switching elements are disproportionately more cost-effective.

By means of power control, any premature outages of EFHs, e.g. associated with the burn-out of lines or failed components, are prevented. Alternatively, the system can be operated at an equal power, using more cost-effective and smaller heating plates, with an equal long-term reliability. EFHs can be employed in various vehicle models, and nevertheless procured as a standard device/generic component for numerous vehicle versions, with respect to installation locations, installation environments and flow conditions of the medium, as a result of which economies of scale can be more effectively exploited. Optimized power control ensures that, for an equal heating effect, an optimized and thus, optionally, a reduced overall power is required. By means of the resulting energy savings, BEVs and PHEVs benefit from a greater maximum range and reduced energy costs for the same distance of travel. Operating states/operating histories can also be taken into consideration, in order to ensure an optimum continuous delivery of heating power for the end-user. A further advantage is provided in that, by means of pre-installation in the device SW (software), technical modification of operating mode is also enabled at a later date, for example in the event of new findings with respect to failure statistics and warranty conditions which emerge subsequently to the start of production of the vehicle. In this case, only a SW update is required which, in any event, is customary during the service life of a vehicle, in order to execute the setting of the improved and corrected operating mode. As a result, no mechanical repair costs are generated, and measures can be effectively implemented prior to the occurrence of a failure in vehicles, thus improving robustness.

It is thus demonstrated how the present disclosure enables a prevention of hotspots in an electrical flow heater.

List of reference numbers

| | |
|---|---|
| 10 | Vehicle |
| 11 | Energy source |
| 12 | Vehicle component |
| 14 | Flow heater |
| 15 | Heating circuit |
| 16 | Medium |
| 17 | Valve |
| 18 | Terminal apparatus |
| 19 | On-board network |
| 20 | Control circuit |
| 21 | On-board communication network |
| 22 | Component |
| 23 | Situation data |
| 24 | Sensor circuit |
| 25 | Sensor data |
| 26 | Installation location |
| 30 | Heating plates |
| 31 | Heating circuits |
| 32 | Total heating power |
| 33 | Switching element |
| 34 | Heating wires |
| 36 | Radiation |
| 37 | Shielding |
| 38 | Arrangement |
| 40 | Configuration data |

1.-15. (canceled)

16. A method for operating an electric flow heater in a vehicle, wherein the flow heater comprises multiple electrical heating circuits for electrical generation of a respective heating power in a heating section through which a medium which is to be heated flows, the method comprising:
actuating, via a control circuit, a respective controllable electrical switching element of the respective heating circuit, in order to execute a power control of the respective heating power of the respective heating circuit, wherein a sum of the heating powers is adjusted to a total heating power, wherein
the control circuit executes a distribution of a total heating power into the heating powers of the heating circuits, in accordance with configuration data, wherein the distribution, which is defined by the configuration data, is independent of current temperature of the medium which is to be heated.

17. The method according to claim 16, wherein
the configuration data of the control circuit are permanently stipulated, or are modified during operation of the control circuit, or
a selection of different configuration data is executed by the control circuit, depending upon a current operating situation detected, and the actuation of heating circuits is executed in accordance with the configuration data selected.

18. The method according to claim 16, wherein, via the configuration data, a condition for actuating the switching elements is stipulated by the control circuit, which dictates a respective upper limit for the heating power of one, a number, or each of the heating circuits.

19. The method according to claim 16, wherein, via the configuration data, a condition which is to be fulfilled by the control circuit is stipulated which provides for a coordinated switching of the switching elements of at least two of the heating circuits, the electrical heating lines of which are arranged in the flow heater in direct mutual proximity, wherein
coordinated switching provides for a dependence of the heating power and/or a circuit state of one of the heating circuits which is switched in a coordinated manner upon the heating power and/or circuit state of another of the heating circuits which is switched in a coordinated manner.

20. The method according to claim 16, wherein, via the configuration data, a condition which is to be fulfilled by the control circuit is stipulated which dictates a synchronized switching.

21. The method according to claim 20, wherein the synchronized switching is a staggered and/or phase-displaced switching of at least two of the switching elements.

22. The method according to claim 21, wherein
the phase-displaced switching is dictated for such heating circuits, the electrical heating lines of which and/or the electric power supply lines of which are arranged in immediate mutual proximity.

23. The method according to claim 20, wherein, via the control circuit, actuation of the switching elements is executed in the form of a pulse-width modulation (PWM) and, via the configuration data, synchronized switching is dictated for all, or only for a number of switching frequencies which are provided for PWM.

24. The method according to claim 16, wherein
the configuration data provide for different installation positions and/or spatial installation locations of the flow heater in the vehicle and/or for different distributions of the total heating power for different vehicle models, and,
via the control circuit, said configuration data are selected as are provided for the actual installation position and/or installation location of the flow heater, and actuation is executed according to the configuration data selected.

25. The method according to claim 16, wherein
the control circuit executes a different setting of the distribution of the total heating power and/or a different actuation of switching elements, according to configuration data for different operating states of the flow heater, which different operating states are distinguished with respect to flow conditions of the medium, and/or for different operating modes, which different operating modes are distinguished with respect to a fluidic coupling of the heating section with different vehicle components of the vehicle.

26. The method according to claim 16, wherein, via the control circuit, in accordance with the configuration data, the distribution of the total heating power and/or the actuation of switching elements is executed based on a respective operating history, which operating history indicates an age and/or hours of service and/or a total quantity of energy converted by the respective heating circuit.

27. The method according to claim 16,
wherein, via the configuration data for different potential operating situations which are continuously and/or presently provided for the flow heater in the vehicle, differing proportional components of the respective heating power in the total heating power and/or upper power limits for one or more, or for all of, the heating circuits are dictated and, via the control circuit, situation data are ascertained which indicate the actual operating situation, and actuation is executed in accordance with the associated configuration data, and/or
wherein configuration data incorporate a code flag, according to the state of which a control is executed to the effect that distribution is only activated in accordance with a vehicle parameter logic, with respect to a national version, a target market, material variants of the heating plates and/or in consideration of a dedicated cold climate vehicle.

28. The method according to claim 27, wherein
the situation data are ascertained from an on-board communication network to which the control circuit is coupled, and/or by a sensor circuit of the flow heater.

29. The method according to claim 16, wherein
the control circuit, further to an employment of configuration data and in a servicing mode, receives new configuration data, and the configuration data are entirely or partially replaced and/or expanded by the new configuration data received.

30. An electrical flow heater, comprising:
multiple electrical heating circuits, each of which is connected via a respective and controllable electric switching element to a terminal apparatus for supplying electrical energy to the respective heating circuit;
a control circuit of the flow heater for power control of electric power which is converted via the switching elements in the respective heating circuit,
wherein the control circuit is operatively configured to:
actuate, via a control circuit, a respective controllable electrical switching element of the respective heating circuit, in order to execute a power control of the respective heating power of the respective heating circuit, wherein a sum of the heating powers is adjusted to a total heating power, wherein
the control circuit executes a distribution of a total heating power into the heating powers of the heating circuits, in accordance with configuration data, wherein the distribution, which is dictated by the configuration data, is independent of current temperature of the medium which is to be heated is designed for executing a method according to one of the preceding claims.

31. A vehicle comprising an electrical flow heater according to claim 30.

32. The vehicle according to claim 31, wherein the vehicle is an electric vehicle.
